(19) United States
(12) Patent Application Publication
(10) Pub. No.: US 2025/0085216 A1
(43) Pub. Date: Mar. 13, 2025

(54) EXAMINING METHOD FOR A COATING LAYER ON A WAFER

(71) Applicant: INGENTEC CORPORATION, MIAOLI COUNTY (TW)

(72) Inventors: PEI-HSUAN CHIANG, MIAOLI COUNTY (TW); CHENG-YU CHUNG, MIAOLI COUNTY (TW)

(21) Appl. No.: 18/531,237

(22) Filed: Dec. 6, 2023

(30) Foreign Application Priority Data
Sep. 13, 2023 (TW) 112134892

(51) Int. Cl. G01N 21/31; G01B 11/06

(52) U.S. Cl. CPC G01N 21/31; G01B 11/0616

(57) ABSTRACT

An examining method for a coating layer on a wafer is provided, including providing an incident light to the coating layer and generating a reflecting light after the coating layer receives the incident light. A spectral analysis of the reflecting light is then generated and compared with a first reference waveform to determine a material of the coating layer. Moreover, the spectral analysis may be further compared with a second reference waveform to determine a thickness of the coating layer. The incident light and reflecting light are provided and received by a spectroscope which is placed above on the wafer to provide perpendicular optical paths to the coating layer on the upper surface of the wafer. By employing the disclosed method, the material and thickness of the coating layer on the wafer can be examined and further classified so as to enhance the conventional efficiency in the prior arts.

### BACKGROUND OF THE INVENTION

This application claims priority for the TW patent application no. 112134892 filed on 13 Sep. 2023, the content of which is incorporated by reference in its entirely.

### FIELD OF THE INVENTION

The present invention relates to an examining method for detecting a coating layer formed on an upper surface of a wafer. More particularly, the present invention is related to an examining method, in which a spectroscope is placed above and used for providing incident light and receiving reflecting light such that a material and thickness of the coating layer on a wafer can be effectively determined and examined.

### DESCRIPTION OF THE PRIOR ART

In general, as known, since the emerging technologies such as Metaverse and autonomous vehicles have brough the developments of Virtual Reality (VR) and Augmented Reality (AR) to grow rapidly, it is believed that the business opportunities for semiconductor wafer industries combined with optical coatings and related sensing optical lenses are gradually increasing at the same time. And due to such huge demands for the semiconductor optical coatings of these new technologies, the optical coating techniques on a wafer are thus playing an important role in the current technologies.

As we know, an optical coating is to apply one or more dielectric films, metal films or a film stack of both on a variety of substrate materials such as glass or wafter using an evaporation process or a sputtering process. By adopting such techniques, the physical properties of various coatings, including the coating thickness, refractive index, and absorption rates can be controlled. Also, the light penetration properties, reflection, and/or semi-reflection of certain wavelengths through the coating may also be designed based on different demands. In the past, the optical coating techniques were applied on flat materials, such as glass substrate. However, in recent years, due to the rapid developments of semiconductor manufacturing processes, in order to design a plurality of photosensitive areas on an integrated chip (IC), the wafer-level multiple optical coating technologies have been proposed these days. And by employing the proposed technologies, it is expected to design multiple photosensitive areas on a variety of IC wafer materials. However, it is noticeable that a wafer surface is usually hardly to control for complete flatness. As a result, it becomes extremely difficult to directly apply the optical coating techniques on a wafer surface and obtain the required optical characteristics as expected.

Based on actual functional and application requirements, the coating layers on a wafer surface are possibly having different materials and coating thickness. In the prior arts, in order to effectively detect and classify the coating layers on the wafer surface, an ellipsometer is usually adopted. Generally, the ellipsometer uses ellipsometry, in which the change of a medium that is related to polarization state of an incident light and a reflected light can be measured such that the optical properties of the medium can be calculated. Since the used ellipsometry is characterized by its non-destructive properties and the improvements of computer technologies have increased the speed of data processing, it makes the ellipsometer be widely applied in semiconductor thin films detection process. As known, the ellipsometry includes reflection ellipsometry, transmission ellipsometry and scattering ellipsometry depending on different configurations. However, in either of these ellipsometry, the change of light intensity amplitude is always taken as the primary data and the light analyzer will be rotated to modulate the incident light signal for performing the measurement, in which a resolution of the measurement result is approximately 3 micro-meters (μm). Since all these methods rely on obtaining the minimum brightness or measuring tiny changes in brightness, the measurement speed is extremely slow. In addition, a high-sensitivity photosensitive component must be employed at the same time to measure the light intensity values of a plurality of light analyzers so as to obtain the elliptical polarization parameters through a Fourier transform or data matching process. It also results in the enormous increasement of the complexity of its system operations, which makes the whole measuring process not only difficult but also time consuming. And thus, it is not suitable for mass application in the industries. Apart from these issues, after the measurement is completed, the following classification of the film layer materials may also be inconvenient and time wasting. If there are not enough effective sample groups for performing comparison and classification, then the time required may also possibly increase significantly. In view of these various deficiencies, it makes the existing ellipsometer until now still have the drawbacks of high process time and cost as well as low efficiency, such that its applications in the related industries are limited so far. As a result, these current technologies have been known as being applied limitedly and thus still not being applicable enough until nowadays.

Therefore, on account of above, to overcome the above mentioned problems, it should be obvious that there is indeed an urgent need for the professionals in the field for a novel and inventive process method to be developed that can effectively solve the above-mentioned problems occurring in the prior techniques, so as to optimize the efficiency for detecting and examining the coating layer on a wafer in a modified manner, especially without using the conventional ellipsometer. As a result, the Applicants of the present invention observe the above deficiencies to be improved, and thus propose a novel examining method for detecting a coating layer on a wafer, especially without using the conventional ellipsometer. Through the disclosed innovative process method, the disclosed examining method can be implemented in an optimal result and superior benefits. Hereinafter, the detailed specific implementations will be fully described in the following paragraphs.

### SUMMARY OF THE INVENTION

In order to overcome the above-mentioned disadvantages, one major objective in accordance with the present invention is provided for a modified examining method for a coating layer on a wafer. By using the provided method, it is operable to detect and classify the coating layer on an upper surface of the wafer. And the provided method can be further widely applied for mass production so as to examine a great number of wafers at one time and to meet the technical needs of related industries for detecting and classifying the various kinds of coating layers on a large number of wafers.

The disclosed examining method of the present invention can be utilized for detecting the coating layer on a silicon substrate wafer. Nevertheless, the present invention is certainly not limited thereto. According to the disclosed examining method of the present invention, it may also be further widely applied to wafers made of other various materials. Many alternatives and modifications will be apparent to those skilled in the art, once informed by the present disclosure, and thus still fall into the claim scope of the present invention.

By adopting the technical contents of the present invention, the conventional examining time which was necessary to be used in the prior arts can be reduced. It only takes less than one second for detecting a piece of wafer. Therefore, the examining efficiency is optimized by employing the present invention. In addition, the classifying yield in the post-end process after the examining procedure is complete can be effectively increased at the same time. As such, detection and classification efficiency of the coating layers on the wafers by the disclosed present invention is obviously optimized.

For achieving the above-mentioned objectives, the Applicants of the present invention disclose an examining method for a coating layer on a wafer. The disclosed examining method includes a plurality of following steps: providing an incident light to the coating layer on the wafer, such that a reflecting light is generated by the coating layer after the coating layer receives the incident light. Later, the reflecting light is received and a spectral analysis of the reflecting light according to the reflecting light is generated. After that, the spectral analysis of the reflecting light will be compared with a first reference waveform. And when the spectral analysis of the reflecting light is identical to the first reference waveform, a consistent outcome will be provided and a material of the coating layer can be determined and confirmed.

According to one embodiment of the present invention, a spectroscope is used for providing the incident light and also for receiving the reflecting light. In detailed configurations, the provided spectroscope is placed directly above the wafer such that the optical paths of the incident light and the reflecting light are both perpendicular to the coating layer on the wafer. According to one preferred embodiment of the present invention, the spectroscope may be used for providing an incident light having a wavelength which is for instance, between 230 and 1000 nanometers. And the spectroscope is placed vertically directly above the wafer to be detected, so as to provide the optical paths as described above.

On the other hand, when the spectral analysis of the reflecting light is different from the first reference waveform, then it is operable to establish a new reference waveform.

Moreover, according to the embodiment of the present invention, before comparing the spectral analysis of the reflecting light with the first reference waveform, the provided examining method of the present invention further includes the steps of entering the first reference waveform into the spectroscope; and presetting a reference spectral reflection index of the first reference waveform according to the first reference waveform. For example, the reference spectral reflection index of the first reference waveform can be determined as “1”, and when the spectral analysis of the reflecting light shows that a spectral reflection index of the reflecting light is greater than “1”, which is the reference spectral reflection index of the first reference waveform, then the material of the coating layer is determined as metal. On the contrary, if the spectral analysis of the reflecting light shows that a spectral reflection index of the reflecting light is less than “1”, which is the reference spectral reflection index of the first reference waveform, then the material of the coating layer is, on the other hand, determined as non-metal.

And furthermore, according to the disclosed examining method of the present invention, then it is also practicable to compare the spectral analysis of the reflecting light with a second reference waveform; and determining a thickness of the coating layer when the spectral analysis is identical to the second reference waveform. According to such manners, then the second reference waveform can be initially entered into the spectroscope; and a reference spectral recognition thickness of the second reference waveform can be determined and preset according to the second reference waveform. In one approach of the present invention, the reference spectral recognition thickness of the second reference waveform can be determined, for instance, in a range of between 900 and 1000 nanometers.

As such, to sum up, according to the technical contents disclosed in the present invention, a computer unit and/or its related algorithm may be adopted for alternatively classifying the coating layer by its material according to the first reference waveform or by the thickness of the coating layer according to the second reference waveform. Alternatively, the classifying criterion may also include both the material and the thickness of the coating layer. Modifications can be made according to various application requirements in the practical needs. Overall, it is believed that by employing the disclosed examining method of the present invention, an automatic process flow can be accomplished and the classifying yield of the coating layers on the wafer under test can be effectively enhanced.

As such, it should be apparent that when those skilled in the art are acknowledged with the technical solutions disclosed in the present invention and adopt the proposed examining method for detecting the coating layer on a wafer, it successfully eliminates the existing issues and deficiencies in the current technologies. Therefore, it can be obvious that the present invention is provided to effectively enhance the examining yield in the current technologies. As such, when compared to the prior conventional technologies, the present invention is certainly characterized by not only having great industrial applicability and technical competitiveness, but also being widely applied in any other related technical fields for mass production and optimizing its process yield. As a result, to sum above, it is apparently obvious that the present invention indeed is beneficial to show great industrial applicability and technical competitiveness in the arts as well as any other related technical fields.

These and other objectives of the present invention will become obvious to those of ordinary skill in the art after reading the following detailed description of preferred embodiments. And it is to be understood that both the foregoing general description and the following detailed description are exemplary and are intended to provide further explanation of the invention as claimed.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, which are served to explain the principles of the invention. In the following drawings:

FIG. 1 schematically shows a process flow chart illustrating the steps of the proposed examining method for a coating layer on a wafer in accordance with one embodiment of the present invention.

FIG. 2 schematically shows a structural diagram of the perpendicular optical paths of the incident light and the reflecting light to the coating layer on the wafer in accordance with the embodiment of the present invention.

FIG. 3 schematically shows a plurality of detailed performing steps of the process flow chart according to FIG. 1.

FIG. 4 schematically shows a waveform diagram of a first reference waveform in accordance with the embodiment of the present invention.

FIG. 5 schematically shows a waveform diagram of a spectral analysis of the reflecting light when a material of the coating layer is metal according to one embodiment of the present invention.

FIG. 6 schematically shows another waveform diagram of a spectral analysis of the reflecting light when a material of the coating layer is metal according to another embodiment of the present invention.

FIG. 7 schematically shows a waveform diagram of a spectral analysis of the reflecting light when a material of the coating layer is non-metal according to one embodiment of the present invention.

FIG. 8 schematically shows another waveform diagram of a spectral analysis of the reflecting light when a material of the coating layer is non-metal according to another embodiment of the present invention.

FIG. 9 schematically shows a waveform diagram of a second reference waveform in accordance with the embodiment of the present invention.

### DESCRIPTION OF THE PREFERRED EMBODIMENTS

It is to be understood that both the foregoing general description and the following detailed description are exemplary and are intended to provide further explanation of the invention as claimed. And references will now be made in detail to the preferred embodiments of the present invention, examples of which are illustrated in the accompanying drawings. Wherever possible, the same reference numbers are used in the drawings and the description to refer to the same or like parts. It is worth noticing that the embodiments described below are illustrated to demonstrate the technical contents and characteristics of the present invention and to enable the persons skilled in the art to understand, make, and use the present invention. However, it shall also be noticed that, it is not intended to limit the scope of the present invention. Therefore, any equivalent modification or variation according to the spirit of the present invention is to be also included within the scope of the present invention.

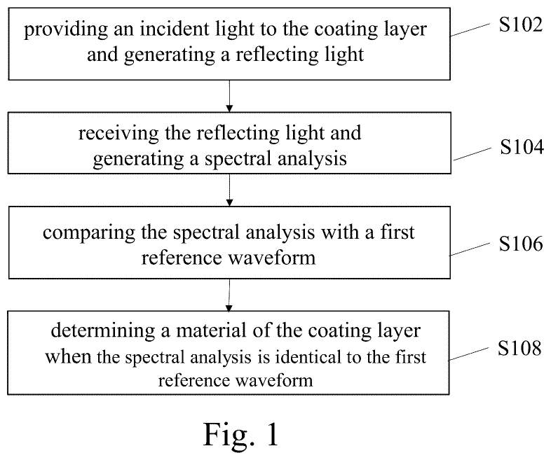

In the following paragraphs, the present invention is aimed to provide an examining method for a coating layer on a wafer. The provided examining method is applicable to a wafer which includes a coating layer disposed on an upper surface of the wafer. According to the embodiment of the present invention, as shown in FIG. 1, the disclosed examining method for a coating layer on a wafer comprises a plurality of steps: S102, S104, S106 and S108, in which a process flow chart illustrating the steps of the proposed examining method for the coating layer on the wafer in accordance with the embodiment of the present invention is provided.

In the beginning, as illustrated in the step of S102, an incident light is provided to the coating layer on the wafer first, such that a reflecting light is generated by the coating layer after the coating layer receives the incident light.

Later, as illustrated in the step of S104, the reflecting light will be collected and received, such that a spectral analysis of the reflecting light according to the reflecting light will be generated in the step of S104. And after obtaining the spectral analysis of the reflecting light, the spectral analysis will be compared with a first reference waveform in the step of S106. And afterwards, as illustrated in the step of S108, when the spectral analysis is identical to the first reference waveform, a consistent outcome will be provided, and a material of the coating layer can be determined according to the first reference waveform.

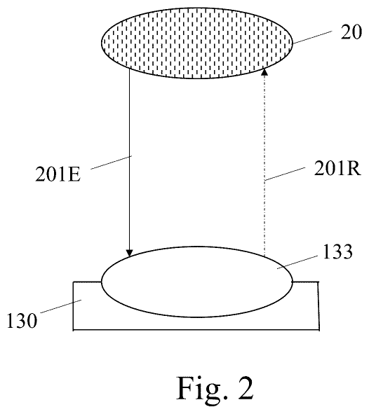

Please refer to FIG. 2 at the same time, in which FIG. 2 schematically shows a structural diagram of the optical paths of the incident light and the reflecting light of the coating layer on the wafer in accordance with the embodiment of the present invention. As can be seen in FIG. 2, when employing the disclosed method of the present invention, it is applicable to place a spectroscope 20 and the spectroscope 20 is disposed directly above the wafer 130. As shown in FIG. 2, in view of such configurations, the coating layer 133 is formed on an upper surface of the wafer 130, and the spectroscope 20 is used to provide the incident light 201E. When the incident light 201E is provided and projected to the coating layer 133 on the wafer 130, the reflecting light 201R can be generated after the coating layer 133 receives the incident light 201E. According to the embodiment of the present invention, the reflecting light 201R is received by the spectroscope 20. In other words, based on the technical contents of the present invention, since the spectroscope 20 is placed directly above the wafer 130 and its coating layer 133 thereon, it is obvious that the optical paths of the incident light 201E provided by the spectroscope 20 and the reflecting light 201R received by the spectroscope 20 are both perpendicular to the coating layer 133 on the wafer 130. As such, by employing the present invention, it is able to detect and examine the material and film thickness of the coating layer 133 by using the spectroscope 20, as will be described in the following sections.

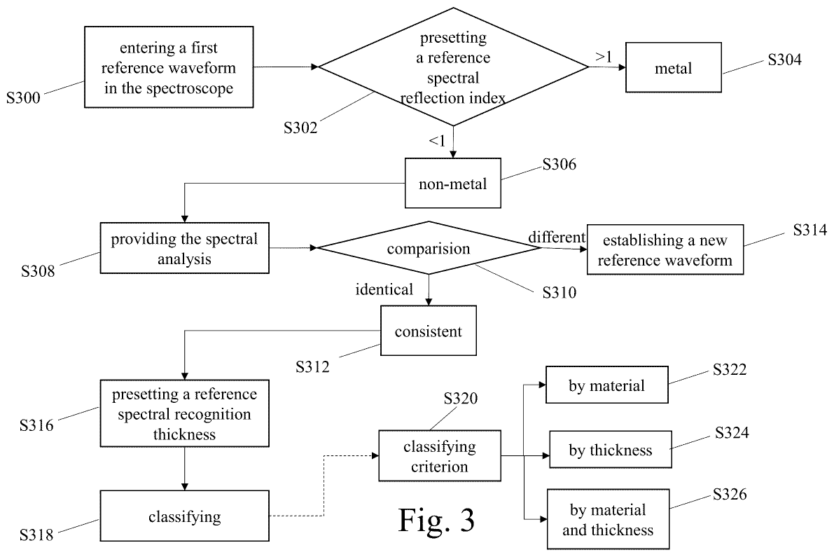

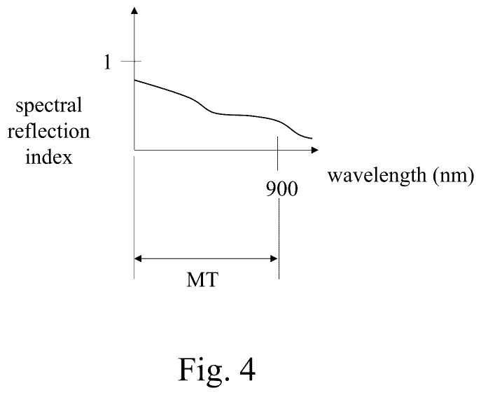

In order to obtain a better understanding and full descriptions of the present invention, please refer to FIG. 3, in which FIG. 3 schematically shows a plurality of detailed performing steps of the process flow chart according to FIG. 1. As can be seen in FIG. 3, in the step of S300, a first reference waveform is entered in the above mentioned spectroscope 20. And then, a reference spectral reflection index of the first reference waveform can be preset according to the first reference waveform in the step of S302. According to one preferred embodiment of the present invention, FIG. 4 schematically shows a waveform diagram of the first reference waveform in accordance with the embodiment of the present invention. As illustrated in FIG. 4, it is shown that the reference spectral reflection index of the first reference waveform, for example, can be determined and preset as “1”. And the area shown in this figure is determined as its material classifying area MT.

Based on such configurations, when the spectral analysis of the reflecting light 201R shows that the spectral reflection index of the reflecting light 201R is greater than the reference spectral reflection index of the first reference waveform, i.e. “1”, then it is determined that the material of the coating layer 133 on the wafer 130 is metal (as indicated by the step of S304 in FIG. 3). On the other hand, if the spectral analysis of the reflecting light 201R shows that the spectral reflection index of the reflecting light 201R is less than the reference spectral reflection index of the first reference waveform, i.e. “1”, then it is determined that the material of the coating layer 133 on the wafer 130 is non-metal (as indicated by the step of S306 in FIG. 3).

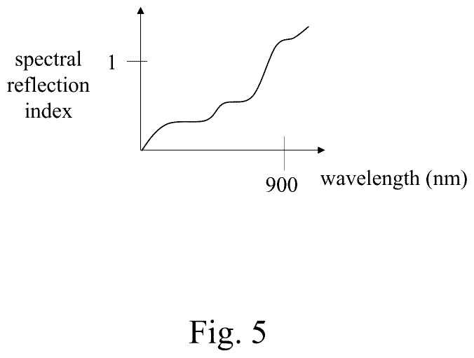

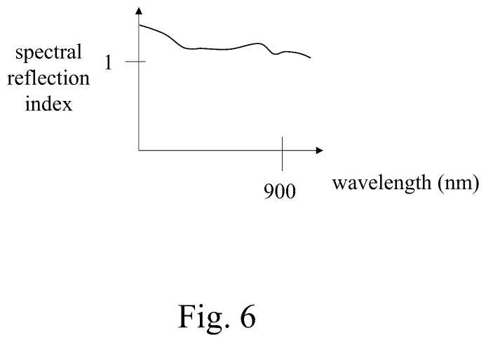

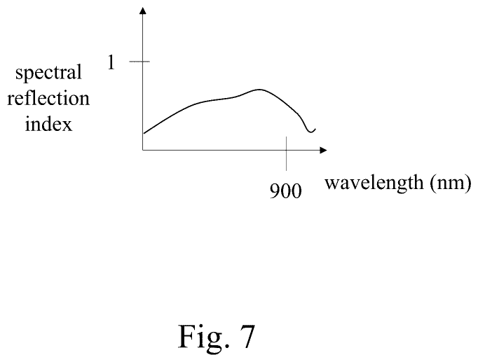

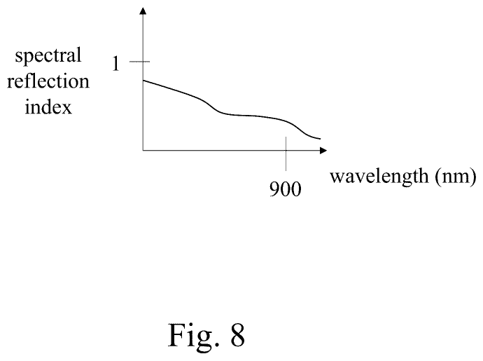

For instance, please refer to FIG. 5 and FIG. 6, which reveal two various waveform diagrams of a spectral analysis of the reflecting light when a material of the coating layer is metal. As illustrated in these two figures, the spectral reflection index of the reflecting light is greater than “1”, And the present invention is able to examine and confirm that the material of the coating layer is metal. On the contrary, FIG. 7 and FIG. 8 reveal another two various waveform diagrams of a spectral analysis of the reflecting light when a material of the coating layer is non-metal. As illustrated in these two figures, it is obvious that the spectral reflection index of the reflecting light is less than “1”, And by employing these two waveform diagrams in FIG. 7 and FIG. 8, the present invention is able to examine and confirm that the material of the coating layer is non-metal. As a result, by comparing the spectral analysis of the reflecting light with the reference spectral reflection index of the first reference waveform, the material of the coating layer on the examined wafer can be effectively determined by employing the disclosed method of the present invention.

As shown in the steps of S308 to S310 in FIG. 3, the present invention proceeds to provide the spectral analysis of the reflecting light and compare the spectral analysis of the reflecting light with the first reference waveform in the step of S310. When the spectral analysis of the reflecting light is identical to the first reference waveform, a consistent outcome is provided in the step of S312. Otherwise, if the spectral analysis of the reflecting light is different from the first reference waveform, then a new reference waveform will be established in the step of S314.

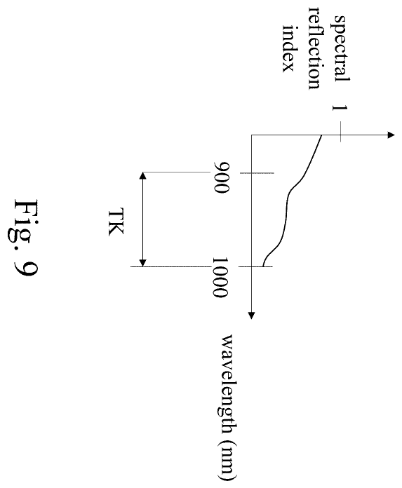

Moreover, according to the above mentioned examining method of the present invention, after the material of the coating layer on the wafer is detected and confirmed, the thickness of the coating layer may also be examined and confirmed by employing the present invention. In specific, please refer to the step of S316 in FIG. 3. In the step of S316, a second reference waveform can be entered into the spectroscope; and a reference spectral recognition thickness of the second reference waveform according to the second reference waveform can be further determined and preset in such performing step. Please refer to FIG. 9 at the same time, in which FIG. 9 schematically shows a waveform diagram of the second reference waveform in accordance with the embodiment of the present invention. As can be seen in FIG. 9, it is apparent that the reference spectral recognition thickness of the second reference waveform, for instance, can be determined as in a range of between 900 and 1000 nanometers. Under such a condition, it is believed that the area shown in this figure between 900 and 1000 nanometers can be determined as its thickness classifying area TK.

On account of the technical contents as described earlier in the present invention, then it is practicable to compare the spectral analysis of the reflecting light of the coating layer with the provided second reference waveform and determine the thickness of the coating layer when the spectral analysis is identical to the second reference waveform. As a result, after the thickness of the coating layer on the wafer is examined, detected and confirmed, a classifying procedure can be carried out in the step of S318. For instance, when performing the step of S318, a computer unit or a central processing unit (CPU) may selectively be adopted for determining the classifying criterion in the step of S320. In one embodiment, it is possible to perform the classifying procedure based on the material of the coating layer according to the first reference waveform. As shown in the step of S322, the disclosed method is able to classify the examined coating layer by different materials. Or in another embodiment, it may also be feasible to perform the classifying procedure based on the thickness of the coating layer according to the second reference waveform. As a result, as shown in the step of S324, then the disclosed method may also be able to classify the examined coating layer by different thickness. Alternatively, it may also be practicable to perform the classifying procedure based on both the material of the coating layer according to the first reference waveform and the thickness of the coating layer according to the second reference waveform as shown in the step of S326. Under such a classifying criterion, then the disclosed method is able to classify the examined coating layer according to both a material and a thickness value thereof.

To sum up, it is worth noting that the classifying criterion disclosed above are merely provided as some of the embodiments of the present invention. For people who are familiar in the technical fields and having common knowledge backgrounds, various modifications and/or other classifying criterion based on wafers and coating layers of different kinds may also be allowed in view of various practical application requirements. That is to say, the present invention is certainly not limited thereto the embodiments as cited in the above illustrative embodiments of this application.

As a result, to conclude from the above disclosed technical contents of the present invention, it is evident that the proposed method for examining a coating layer on a wafer is performed by adopting a spectroscope which provides an incident light having wavelength of 230 to 1000 nanometers. The provided spectroscope is placed directly above the under-test coating layer of the wafer such that the optical paths of the incident light and of the reflecting light after the coating layer receives the incident light are both perpendicular to the coating layer on the upper surface of the wafer. After that, a spectral analysis of the reflecting light can be carried out so as to be compared with certain reference waveforms. By employing such technical solution, the material and thickness of the coating layer on the wafer can be effectively examined, confirmed, and classified in the post-end processes.

Therefore, based on at least one embodiment of the present invention as disclosed above, it can be seen that, the technical advantages of the proposal of the present invention include that the overall operation method and its process can be made automatically, and through the disclosed method and process, it can effectively reduce the time required for conventional detection. For example, for detecting one piece of wafer, less than one second is needed. As a result, it is believed that the whole examining and detecting efficiency of the under-test wafer can be enhanced and optimized. In addition, according to the examining method disclosed in the present invention, the yield for classification of the coating layer on the wafer can be further effectively increased and optimized as well.

Apart from the above, according to the proposed technical solution provided by the Applicants of the invention, it is believed that a rapid and mass-transfer result may also be accomplished when adopting the disclosed method for examining a great number of wafers in the industries. Therefore, it is believed that the present invention not only meets up with the requirement for rapidly examining numerous wafers at one time, but also effectively enhance its competitiveness regarding industrial production. Under such circumstances, the present invention not only results in effectively improving the existing shortcomings in the prior arts, but also complies with the requirements for mass production, thereby realizing the superior effects of the present invention.

As a result, to sum up, according to the several embodiments and the technical contents disclosed by the present invention, it is believed that the disclosed examining method not only solves the drawbacks existing in the current technologies, but also provides an optimal examining and classifying result. In addition, the proposed examining method of the present invention can be applied to not only general wafers made of silicon, but also any various related electronic circuit components in the semiconductor industry, integrated circuit industry, or power electronics industry. In view of all, the Applicants assert that the present invention is instinct, effective and highly competitive for incoming technologies, industries and research developed in the future. And since the technical features, means and effects achieved by the present invention are significantly different from the current solutions and can not be accomplished easily by those who are familiar with the industry, it is thus believed that the present invention is indeed characterized by patentability and shall be patentable soon in a near future.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. An examining method for a coating layer on a wafer, which is applicable to the wafer which includes the coating layer disposed on an upper surface of the wafer, the examining method comprising:
providing an incident light to the coating layer on the wafer, and generating a reflecting light after the coating layer receives the incident light;
receiving the reflecting light and generating a spectral analysis of the reflecting light according to the reflecting light;
comparing the spectral analysis with a first reference waveform; and
determining a material of the coating layer when the spectral analysis is identical to the first reference waveform and a consistent outcome is provided.

2. The examining method according to claim 1, further comprising establishing a new reference waveform when the spectral analysis of the reflecting light is different from the first reference waveform.

3. The examining method according to claim 1, wherein the incident light is provided by a spectroscope.

4. The examining method according to claim 3, wherein the reflecting light is received by the spectroscope.

5. The examining method according to claim 3, wherein the spectroscope is disposed directly above the wafer such that optical paths of the incident light and the reflecting light are perpendicular to the coating layer on the wafer.

6. The examining method according to claim 3, before the step of comparing the spectral analysis with the first reference waveform, further comprising:
entering the first reference waveform into the spectroscope; and
presetting a reference spectral reflection index of the first reference waveform according to the first reference waveform.

7. The examining method according to claim 6, wherein the material of the coating layer is determined as metal when the spectral analysis shows that a spectral reflection index of the reflecting light is greater than the reference spectral reflection index of the first reference waveform.

8. The examining method according to claim 6, wherein the material of the coating layer is determined as non-metal when the spectral analysis shows that a spectral reflection index of the reflecting light is less than the reference spectral reflection index of the first reference waveform.

9. The examining method according to claim 6, wherein the reference spectral reflection index of the first reference waveform is 1.

10. The examining method according to claim 1, further comprising:
comparing the spectral analysis with a second reference waveform; and
determining a thickness of the coating layer when the spectral analysis is identical to the second reference waveform.

11. The examining method according to claim 10, further comprising:
entering the second reference waveform into a spectroscope; and
presetting a reference spectral recognition thickness of the second reference waveform according to the second reference waveform.

12. The examining method according to claim 11, wherein the incident light is provided by the spectroscope.

13. The examining method according to claim 11, wherein the reflecting light is received by the spectroscope.

14. The examining method according to claim 11, wherein the spectroscope is disposed directly above the wafer such that optical paths of the incident light and the reflecting light are perpendicular to the coating layer on the wafer.

15. The examining method according to claim 11, wherein the reference spectral recognition thickness of the second reference waveform is between 900 and 1000 nanometers.

16. The examining method according to claim 11, wherein a computer unit is adopted for alternatively classifying the coating layer by the material according to the first reference waveform or by the thickness according to the second reference waveform.
